(19) United States
(12) Patent Application Publication
(10) Pub. No.: US 2021/0358828 A1
(43) Pub. Date: Nov. 18, 2021

(54) CHIP ON FILM AND DISPLAY DEVICE

(71) Applicant: TCL China Star Optoelectronics Technology Co., LTD., Shenzhen, Guangdong (CN)

(72) Inventors: Nianmao WANG, Shenzhen (CN); Gu HUANG, Shenzhen (CN)

(21) Appl. No.: 16/617,067

(22) PCT Filed: Nov. 12, 2019
(86) PCT No.: PCT/CN2019/117594

§ 371 Date: Nov. 26, 2019

(30) Foreign Application Priority Data
Sep. 30, 2019 (CN) 201910940975.5

(51) Int. Cl. H01L 23/367

(52) U.S. Cl. CPC H01L 23/3677

(57) ABSTRACT

The disclosure provides a chip on film (COF) and a display device. The COF includes a substrate, a driver chip, and a heat dissipation component. A plurality of signal terminals and a plurality of heat dissipation terminals are formed on the substrate. The driver chip includes a plurality of signal pins and a plurality of heat dissipation pins. The signal pins are connected to the signal terminals, and the heat dissipation pins are connected to the heat dissipation terminals. By disposing the heat dissipation pins on the driver chip, heat generated from the driver chip may be dissipated. Therefore, a large heat dissipation area of the driver chip may be realized, which solves a problem that temperatures of conventional COFs are too high.

### FIELD

The present disclosure relates to the display field and, more particularly, relates to a chip on film and a display device.

### BACKGROUND

With increasing terminal user's demands for image quality of liquid crystal display (LCD) panels, resolutions of LCD panels have become increasingly higher. The higher the resolutions of the LCD panels are, the more output channels a chip on film (COF) has, and the greater power consumption the COF has. Increased power consumption is usually accompanied by increased temperatures of the COF, which may reach 200 Celsius degrees. However, to ensure safety of products, temperatures of the COF need to be controlled below 100 Celsius degrees.

Consequently, it is necessary to solve a problem that temperatures of conventional COFs are too high.

Regarding technical problem: The present disclosure provides a COF and a display device to solve the problem that temperatures of conventional COFs are too high.

### SUMMARY

To solve the above problem, technical solutions provided by the present disclosure are described as follows:

The present disclosure provides a chip on film (COF), including: a substrate, wherein a plurality of signal terminals and a plurality of heat dissipation terminals are formed on the substrate; and a driver chip bonded to the substrate, wherein the driver chip includes a plurality of signal pins and a plurality of heat dissipation pins. The signal pins are connected to the signal terminals, and the heat dissipation pins are connected to the heat dissipation terminals.

In the COF provided by the present disclosure, the heat dissipation pins are disposed on a middle portion of the driver chip.

In the COF provided by the present disclosure, the heat dissipation pins are disposed on a periphery of the driver chip.

In the COF provided by the present disclosure, the heat dissipation pins are disposed on a middle portion of the driver chip.

In the COF provided by the present disclosure, the heat dissipation pins are disposed on a middle portion of the driver chip.

In the COF provided by the present disclosure, the heat dissipation terminals and the signal terminals are disposed on a same row.

In the COF provided by the present disclosure, the heat dissipation terminals and the signal terminals are disposed on different rows.

In the COF provided by the present disclosure, the heat dissipation terminals are disposed outwardly with respect to the signal terminals.

In the COF provided by the present disclosure, shapes of the heat dissipation terminals are one or more of a circle, a rectangle, and an octagon.

In the COF provided by the present disclosure, the COF further includes a heat dissipation component covering the driver chip.

The present disclosure further provides a display device, including a chip on film (COF), and the COF includes: a substrate, wherein a plurality of signal terminals and a plurality of heat dissipation terminals are formed on the substrate; and a driver chip bonded to the substrate, wherein the driver chip includes a plurality of signal pins and a plurality of heat dissipation pins. The signal pins are connected to the signal terminals, and the heat dissipation pins are connected to the heat dissipation terminals.

In the display device provided by the present disclosure, the heat dissipation pins are disposed on a middle portion of the driver chip.

In the display device provided by the present disclosure, the heat dissipation pins are disposed on a middle portion of the driver chip.

In the display device provided by the present disclosure, the heat dissipation pins are disposed on a middle portion of the driver chip.

In the display device provided by the present disclosure, the heat dissipation pins are disposed on a middle portion of the driver chip.

In the display device provided by the present disclosure, the heat dissipation terminals and the signal terminals are disposed on a same row.

In the display device provided by the present disclosure, the heat dissipation terminals and the signal terminals are disposed on different rows

In the display device provided by the present disclosure, the heat dissipation terminals are disposed outwardly with respect to the signal terminals.

In the display device provided by the present disclosure, shapes of the heat dissipation terminals are one or more of a circle, a rectangle, and an octagon.

In the display device provided by the present disclosure, the COF further includes a heat dissipation component covering the driver chip.

Regarding beneficial effects: The present disclosure provides a COF and a display device. The COF includes a substrate, a driver chip, and a heat dissipation component. A plurality of signal terminals and a plurality of heat dissipation terminals are formed on the substrate. The driver chip is bonded to the substrate and includes a plurality of signal pins and a plurality of heat dissipation pins. The signal pins are connected to the signal terminals, and the heat dissipation pins are connected to the heat dissipation terminals. The heat dissipation component covers the driver chip. By disposing the heat dissipation pins on the driver chip, heat generated from the driver chip may be dissipated by the heat dissipation pins. Therefore, a large heat dissipation area of the driver chip may be realized, which effectively reduces temperatures of the COF and solves the problem that temperatures of conventional COFs are too high.

### DESCRIPTION OF DRAWINGS

The accompanying figures to be used in the description of embodiments of the present disclosure or prior art will be described in brief to more clearly illustrate the technical solutions of the embodiments or the prior art. The accompanying figures described below are only part of the embodiments of the present disclosure, from which those skilled in the art can derive further figures without making any inventive efforts.

FIG. 1 is a top view showing a chip on film (COF) provided by an embodiment of the present disclosure.

FIG. 2 is a sectional view along A-A′-B′-B direction in FIG. 1.

FIG. 3(a) is a schematic view showing a substrate of a first COF provided by an embodiment of the present disclosure.

FIG. 3(b) is a schematic view showing a driver chip of the first COF provided by an embodiment of the present disclosure.

FIG. 4(a) is a schematic view showing a substrate of a second COF provided by an embodiment of the present disclosure.

FIG. 4(b) is a schematic view showing a driver chip of the second COF provided by an embodiment of the present disclosure.

FIG. 5(a) is a schematic view showing a substrate of a third COF provided by an embodiment of the present disclosure.

FIG. 5(b) is a schematic view showing a driver chip of the third COF provided by an embodiment of the present disclosure.

FIG. 6(a) is a schematic view showing a substrate of a fourth COF provided by an embodiment of the present disclosure.

FIG. 6(b) is a schematic view showing a driver chip of the fourth COF provided by an embodiment of the present disclosure.

FIG. 7(a) is a schematic view showing a substrate of a fifth COF provided by an embodiment of the present disclosure.

FIG. 7(b) is a schematic view showing a driver chip of the fifth COF provided by an embodiment of the present disclosure.

FIG. 8 is another sectional view along the A-A-B′-B direction in FIG. 1.

### DETAILED DESCRIPTION

The following description of the various embodiments is provided with reference to the accompanying drawings. It should be understood that terms such as “upper”, “lower”, “front”, “rear”, “left”, “right”, “inside”, “outside”, “lateral”, as well as derivative thereof should be construed to refer to the orientation as then described or as shown in the drawings under discussion. These relative terms are for convenience of description, do not require that the present disclosure be constructed or operated in a particular orientation, and shall not be construed as causing limitations to the present disclosure. In the drawings, the identical or similar reference numerals constantly denote the identical or similar elements or elements having the identical or similar functions.

A COF provided by the present disclosure can solve the problem that temperatures of conventional COFs are too high.

In one embodiment, as shown in FIG. 2, the COF provided by the present disclosure includes: a substrate 10, wherein a plurality of signal terminals 101 and a plurality of heat dissipation terminals 102 are formed on the substrate 10; and a driver chip 20 bonded to the substrate 10, wherein the driver chip 20 includes a plurality of signal pins 201, a plurality of heat dissipation pins 202, and a driver chip body 203.

The signal pins 201 are connected to the signal terminals 101, and the heat dissipation pins 202 are connected to the heat dissipation terminals 102.

The present disclosure provides a COF and a display device. By disposing the heat dissipation pins on the driver chip, heat generated from the driver chip may be dissipated by the heat dissipation pins. Therefore, a large heat dissipation area of the driver chip may be realized, which effectively reduces temperatures of the COF and solves the problem that temperatures of conventional COF are too high.

Different disposing ways of the heat dissipation pins 202, the heat dissipation terminals 102, and the heat dissipation component 30 result in different heat dissipation effects of the driver chip 20. The COF of the present disclosure is further described below with reference to specific embodiments.

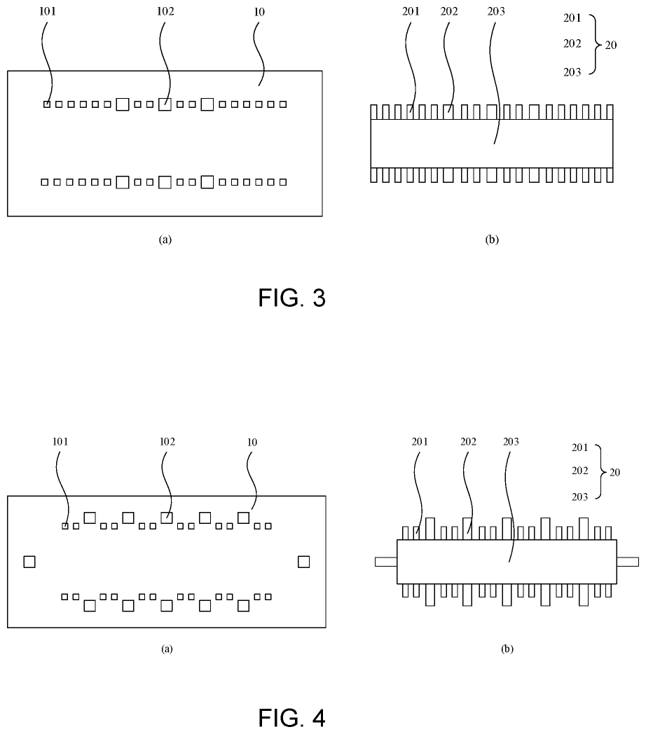

In one embodiment, as shown in FIG. 3(a), the heat dissipation terminals 102 and the signal terminals 101 are disposed on the same row. A side of the heat dissipation terminals 102 is connected to the ground with large-area copper. As shown in FIG. 3(b), because heat generated from the driver chip 20 is mainly concentrated in a middle portion of the driver chip body 203, the heat dissipation pins 202 are disposed on the middle portion of the driver chip 20 and are connected to the driver chip body 203. Furthermore, the heat dissipation pins 202 and the signal pins 201 are spaced from each other. Therefore, after the heat dissipation pins 202 are connected to the heat dissipation terminals 102, heat concentrated in the middle portion of the driver chip body 203 will be transferred into the ground by the heat dissipation pins 202 and the heat dissipation terminals 102, and then be dissipated by the large-area copper, realizing heat dissipation effects of the driver chip 20.

To prevent oxidation, improve conductivity, and weld easily, a preferred material of the heat dissipation pins 202 is copper. Iron may also be a material of the heat dissipation pins 202. A surface of the heat dissipation pins 202 is further plated with tin, silver, or gold. The heat dissipation pins 202 are processed with rare metal. Because metal materials have exceptional heat conductivity, heat concentrated in the middle portion of the driver chip body 203 may be effectively and rapidly transferred outside the driver chip body 203 by the heat dissipation pins 202, and then be transferred into the ground with large-area copper by the heat dissipation terminals 102. Therefore, heat may be dissipated.

The heat dissipation terminals 102 are generally connection pads. To realize great heat dissipation effects, sizes of the connection pads may be appropriately large for connecting with the heat dissipation pins 202. The connection pads and the heat dissipation pins 202 are welded together by solder. To enlarge a contact area between the heat dissipation pins 202 and the ground and improve heat dissipation effects of the driver chip 20, sizes of the heat dissipation pads need to be as large as possible, which are generally larger than sizes of the signal terminals 101. Of course, shapes, sizes, and distributions of the heat dissipation pads may be same as that of the signal terminals 101. By the above arrangement, patterns of welding materials may be prepared consistently; therefore, installation parameters are easy to be decided. Materials of the heat dissipation pads may be one or more selected from the group consisting of Ti, W, Al, Cu, Ni, Pt, Ag, and Au. A material of the solder is one selected from the group consisting of tin-lead alloy solder, twisted solder, cadmium solder, silver solder, or copper solder. The solder further includes solder bar, solder paste, or solder ball. Shapes of the heat dissipation terminals 102 are one or more of a circle, a rectangle, and an octagon.

In the present disclosure, the heat dissipation pins 202 are disposed on the middle portion of the driver chip body 203, from which heat is mainly generated, of the driver chip 20, and the heat dissipation terminals 102 that correspond to the dissipation pins 202 are disposed on a control plate 10. By the simple design, heat generated from the driver chip 20 is dissipated by as few heat dissipation terminals 102 and heat dissipation pins 202 as possible, and temperature of the driver chip 20 is reduced.

In addition, in the present embodiment, in a situation that the heat dissipation pins 202 are disposed on the middle portion of the driver chip 20, the heat dissipation terminals 202 may be disposed on different rows from the signal terminals 101, may be disposed outwardly with respect to the signal terminals 101 (as shown in FIG. 4), or may be disposed inwardly with respect to the signal terminals 101. However, disposing ways of the heat dissipation terminals are not limited to the above three disposing ways.

In one embodiment, as shown in FIG. 4(a), the heat dissipation terminals 102 and the signal terminals 101 are disposed on different rows. The heat dissipation terminals 102 are disposed outwardly with respect to the signal terminals 101. One side of the heat dissipation terminals 102 is connected to the ground with large-area copper. As shown in FIG. 4(b), the dissipation pins 202 are disposed on a periphery of the driver chip 20 and are spaced from the signal pins 201. Therefore, after the heat dissipation pins 202 are connected to the heat dissipation terminals 102, heat distributed across each position of the driver chip body 203 may be transferred into the ground by the heat dissipation pins 202 and the heat dissipation terminals 102, and then be dissipated by the large-area copper, realizing heat dissipation effects of the driver chip 20.

To prevent oxidation, improve conductivity, and weld easily, a preferred material of the heat dissipation pins 202 is copper. Iron may also be a material of the heat dissipation pins 202. A surface of the heat dissipation pins 202 is further plated with tin, silver, or gold. The heat dissipation pins 202 are processed with rare metal. Because metal materials have exceptional heat conductivity, heat concentrated in the middle portion of the driver chip 20 may be effectively and rapidly transferred outside the driver chip 20 by the heat dissipation pins 202, and then be transferred into the ground with large-area copper by the heat dissipation terminals 102. Therefore, heat may be dissipated.

The heat dissipation terminals 102 are generally connection pads. To realize great heat dissipation effects, sizes of the connection pads may be appropriately large for connecting with the heat dissipation pins 202. The connection pads and the heat dissipation pins 202 are connected to each other by solder. To enlarge a contact area between the heat dissipation pins 202 and the ground and improve heat dissipation effects of the driver chip 20, sizes of the heat dissipation pads need to be as large as possible, which is generally larger than sizes of the signal terminals 101. Of course, shapes, sizes, and distributions of the heat dissipation pads may be same as shapes, sizes, and distributions of the signal terminals 101. By the above arrangement, patterns of welding materials may be prepared consistently; therefore, installation parameters are easy to be decided. Materials of the heat dissipation pads may be one or more selected from the group consisting of Ti, W, Al, Cu, Ni, Pt, Ag, and Au. A material of the solder is one selected from the group consisting of tin-lead alloy solder, twisted solder, cadmium solder, silver solder, or copper solder. The solder further includes solder bar, solder paste, or solder ball. Shapes of the heat dissipation terminals 102 are one or more of a circle, a rectangle, and an octagon.

In the present disclosure, the heat dissipation pins 202 are disposed on the periphery of the driver chip 20. The heat dissipation terminals 102 that correspond to the dissipation pins 202 are disposed on the control plate 10, realizing effective heat dissipation of each position of the driver chip body 203. Furthermore, the heat dissipation terminals 102 are disposed outwardly with respect to the signal terminals 101. Sizes of the heat dissipation terminals 102 may be as large as possible to enlarge a contact area between the heat dissipation terminals 102 and the ground, thereby improving heat dissipation efficiency, reducing temperature of the driver chip 20, and reducing space occupied by the signal terminals 101.

In addition, in the present disclosure, in a situation that the heat dissipation pins 202 are disposed on the periphery of the driver chip 20, the heat dissipation terminals 102 and the signal terminals 101 may be disposed on the same row as shown in FIG. 3(a). The heat dissipation terminals 102 may also be disposed on different rows from the signal terminals 101 or may be disposed outwardly with respect to the signal terminals 101. However, disposing ways of the dissipation terminals 102 are not limited to the above three disposing ways.

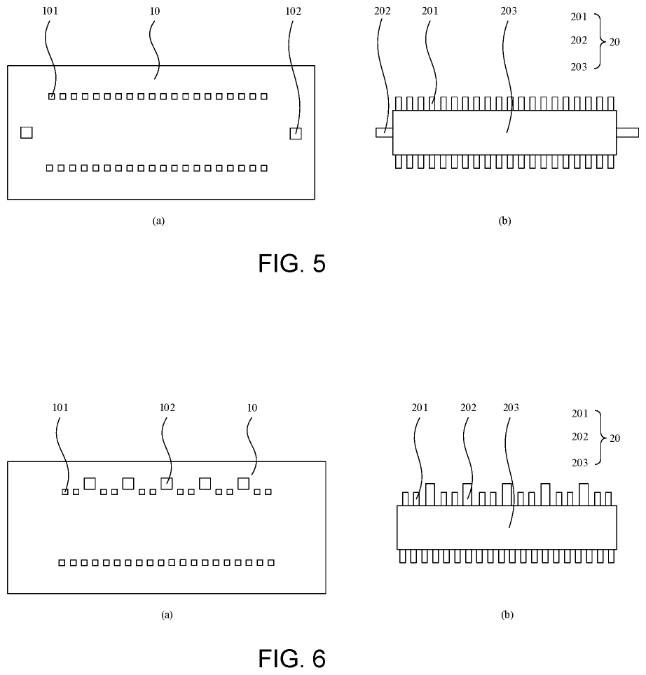

In one embodiment, as shown in FIG. 5(b), the dissipation pins 202 are disposed on the periphery of the driver chip body 203. Therefore, after the heat dissipation pins 202 are connected to the heat dissipation terminals 102, heat of the driver chip body 203 may be transferred into the ground by the heat dissipation pins 202 and the heat dissipation terminals 102, and then be dissipated by the large-area copper.

To prevent oxidation, improve conductivity, and weld easily, a preferred material of the heat dissipation pins 202 is copper. Iron may also be a material of the heat dissipation pins 202. A surface of the heat dissipation pins 202 is further plated with tin, silver, or gold. The heat dissipation pins 202 are processed with rare metal. Because metal materials have exceptional heat conductivity, heat of the driver chip 20 may be effectively and rapidly transferred outside the driver chip 20 by the heat dissipation pins 202, and then be transferred into the ground with large-area copper by the heat dissipation terminals 102. Therefore, heat may be dissipated.

The heat dissipation terminals 102 are generally connection pads. To realize great heat dissipation effects, sizes of the connection pads may be appropriately large for connecting with the heat dissipation pins 202. The connection pads and the heat dissipation pins 202 are connected to each other by solder. To enlarge a contact area between the heat dissipation pins 202 and the ground and improve heat dissipation effects of the driver chip 20, sizes of the heat dissipation pads need to be as large as possible, which is generally larger than sizes of the signal terminals 101. Of course, shapes and sizes of the heat dissipation pads may be same as that of the signal terminals 101. Materials of the heat dissipation pads may be one or more selected from the group consisting of Ti, W, Al, Cu, Ni, Pt, Ag, and Au. A material of the solder is one selected from the group consisting of tin-lead alloy solder, twisted solder, cadmium solder, silver solder, or copper solder. The solder further includes solder bar, solder paste, or solder ball. Shapes of the heat dissipation terminals 102 are one or more of a circle, a rectangle, and an octagon.

In the present disclosure, the heat dissipation pins 202 are disposed on the periphery of the driver chip body 203. The heat dissipation terminals 102 that correspond to the dissipation pins 202 are disposed on the control plate 10, thereby realizing heat dissipation effects of the driver chip body 203. In addition, the heat dissipation pins 202 are disposed on the periphery of the driver chip body 203 so that space in which the signal pins 201 are disposed will not be occupied. Therefore, a connection way of the driver chip 20 will not be affected.

In one embodiment, as shown in FIG. 6(a), the heat dissipation terminals 102 and the signal terminals 101 are disposed on different rows. The heat dissipation terminals 102 are disposed outwardly with respect to the signal terminals 101. One side of the heat dissipation terminals 102 is connected to ground with large-area copper. As shown in FIG. 4(b), the dissipation pins 202 are disposed on one side of the driver chip 20 and are spaced from the signal pins 201. Therefore, after the heat dissipation pins 202 are connected to the heat dissipation terminals 102, heat of the driver chip 20 may be transferred into the ground by the heat dissipation pins 202 which are disposed on a side of the driver chip 20 and the heat dissipation terminals 102, and then be dissipated by the large-area copper, realizing heat dissipation effects of the driver chip 20.

To prevent oxidation, improve conductivity, and weld easily, a preferred material of the heat dissipation pins 202 is copper. Iron may also be a material of the heat dissipation pins 202. A surface of the heat dissipation pins 202 is further plated with tin, silver, or gold. The heat dissipation pins 202 are processed with rare metal. Because metal materials have exceptional heat conductivity, heat concentrated in the middle portion of the driver chip 20 may be effectively and rapidly transferred outside the driver chip 20 by the heat dissipation pins 202, and then be transferred into the ground with large-area copper by the heat dissipation terminals 102. Therefore, heat may be dissipated.

The heat dissipation terminals 102 are generally connection pads. To realize great heat dissipation effects, sizes of the connection pads may be appropriately large for connecting with the heat dissipation pins 202. The connection pads and the heat dissipation pins 202 are connected to each other by solder. To enlarge a contact area between the heat dissipation pins 202 and the ground and improve heat dissipation effects of the driver chip 20, sizes of the heat dissipation pads need to be as large as possible, which is generally larger than sizes of the signal terminals 101. Of course, shapes, sizes, and distributions of the heat dissipation pads may be same as shapes, sizes, and distributions of the signal terminals 101. By the above arrangement, patterns of welding materials may be prepared consistently; therefore, installation parameters are easy to be decided. Materials of the heat dissipation pads may be one or more selected from the group consisting of Ti, W, Al, Cu, Ni, Pt, Ag, and Au. A material of the solder is one selected from the group consisting of tin-lead alloy solder, twisted solder, cadmium solder, silver solder, or copper solder. The solder further includes solder bar, solder paste, or solder ball. Shapes of the heat dissipation terminals 102 are one or more of a circle, a rectangle, and an octagon.

In the present disclosure, the heat dissipation pins 202 are disposed on a side of the driver chip 20. The heat dissipation terminals 102 that correspond to the dissipation pins 202 are disposed on the control plate 10, realizing effective heat dissipation of each position of the driver chip 20 by as less heat dissipation terminals 102 and heat dissipation pins 202 as possible. Furthermore, the heat dissipation terminals 102 are disposed outwardly with respect to the signal terminals 101. Sizes of the heat dissipation terminals 102 may be as large as possible to enlarge a contact area between the heat dissipation terminals 102 and the ground, thereby improving heat dissipation efficiency, reducing temperature of the driver chip 20, and reducing space occupied by the signal terminals 101.

In addition, in the present disclosure, in a situation that the heat dissipation pins 202 are disposed on the side of the driver chip 20, the heat dissipation terminals 102 and the signal terminals 101 may be disposed on a same row as shown in FIG. 3(a). The heat dissipation terminals 102 may also be disposed on different rows from the signal terminals 101 or may be disposed outwardly with respect to the signal terminals 101. However, disposing ways of the dissipation terminals 102 are not limited to the above three disposing ways.

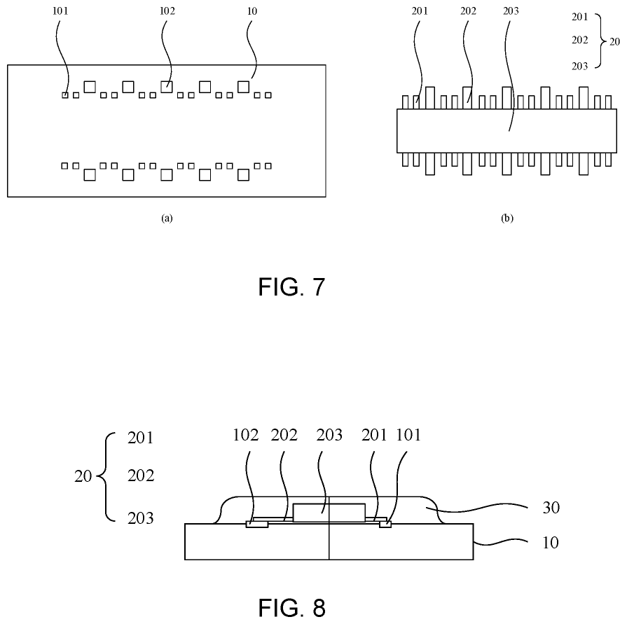

In one embodiment, as shown in FIG. 7(a), the heat dissipation terminals 102 and the signal terminals 101 are disposed on different rows. The heat dissipation terminals 102 are disposed outwardly with respect to the signal terminals 101. One side of the heat dissipation terminals 102 is connected to ground with large-area copper. As shown in FIG. 7(b), the dissipation pins 202 are disposed on two sides of the driver chip 20 and are spaced from the signal pins 201. Therefore, after the heat dissipation pins 202 are connected to the heat dissipation terminals 102, heat of the driver chip 20 may be transferred into the ground by the heat dissipation pins 202 which are disposed on the side of the driver chip 20 and the heat dissipation terminals 102, and then be dissipated by the large-area copper, realizing heat dissipation effects of the driver chip 20.

To prevent oxidation, improve conductivity, and weld easily, a preferred material of the heat dissipation pins 202 is copper. Iron may also be a material of the heat dissipation pins 202. A surface of the heat dissipation pins 202 is further plated with tin, silver, or gold. The heat dissipation pins 202 are processed with rare metal. Because metal materials have exceptional heat conductivity, heat concentrated in the middle portion of the driver chip 20 may be effectively and rapidly transferred outside the driver chip 20 by the heat dissipation pins 202, and then be transferred into the ground with large-area copper by the heat dissipation terminals 102. Therefore, heat may be dissipated.

The heat dissipation terminals 102 are generally connection pads. To realize great heat dissipation effects, sizes of the connection pads may be appropriately large for connecting with the heat dissipation pins 202. The connection pads and the heat dissipation pins 202 are connected to each other by solder. To enlarge a contact area between the heat dissipation pins 202 and the ground and improve heat dissipation effects of the driver chip 20, sizes of the heat dissipation pads need to be as large as possible, which is generally larger than sizes of the signal terminals 101. Of course, shapes, sizes, and distributions of the heat dissipation pads may be same as shapes, sizes, and distributions of the signal terminals 101. By the above arrangement, patterns of welding materials may be prepared consistently; therefore, installation parameters are easy to be decided. Materials of the heat dissipation pads may be one or more selected from the group consisting of Ti, W, Al, Cu, Ni, Pt, Ag, and Au. A material of the solder is one selected from the group consisting of tin-lead alloy solder, twisted solder, cadmium solder, silver solder, or copper solder. The solder further includes solder bar, solder paste, or solder ball. Shapes of the heat dissipation terminals 102 are one or more of a circle, a rectangle, and an octagon.

In the present disclosure, the heat dissipation pins 202 are disposed on two sides of the driver chip 20. The heat dissipation terminals 102 that correspond to the dissipation pins 202 are disposed on the control plate 10, realizing effective heat dissipation of each position of the driver chip 20. Furthermore, the heat dissipation terminals 102 are disposed outwardly with respect to the signal terminals 101. Sizes of the heat dissipation terminals 102 may be as large as possible to enlarge a contact area between the heat dissipation terminals 102 and the ground, thereby improving heat dissipation efficiency, reducing temperature of the driver chip 20, and reducing space occupied by the signal terminals 101.

In addition, in the present disclosure, in a situation that the heat dissipation pins 202 are disposed on two sides of the driver chip 20, the heat dissipation terminals 102 and the signal terminals 101 may be disposed on the same row as shown in FIG. 3(a). The heat dissipation terminals 102 may also be disposed on different rows from the signal terminals 101 or may be disposed outwardly with respect to the signal terminals 101. However, disposing ways of the dissipation terminals 102 are not limited to the above three disposing ways.

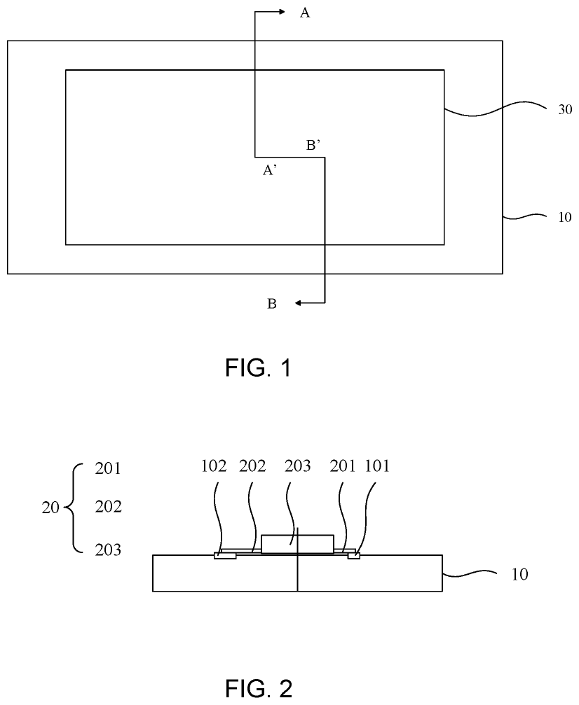

In one embodiment, as shown in FIG. 1 and FIG. 2, a heat dissipation component 30 is further disposed on the driver chip 20. The heat dissipation component 30 covers the signal pins 201, the heat dissipation pins 202, and the driver chip body 203 of the driver chip 20. The heat dissipation component 30 is a layer of an insulating and heat dissipation material, and a preferred material is an epoxy resin. The epoxy resin has exceptional heat dissipation performance and great flowability so that it can fill gaps between the driver chip body 203, the heat dissipation pins 202, and the heat dissipation terminals 102 and make them better contact with each other. Heat generated from the driver chip body 203 can be dissipated into ambient air by the epoxy resin which is directly in contact with the driver chip 20 and by the epoxy resin which is in contact with the heat dissipation pins 202 and the heat dissipation terminals 102. Furthermore, heat transferred into the epoxy resin can also be dissipated into the ground by the heat dissipation terminals 102, thereby promoting heat dissipation of the driver chip 20 and reducing temperature of the COF.

An embodiment of the present disclosure provides a display device including a chip on film (COF), wherein the COF includes: a substrate, wherein a plurality of signal terminals and a plurality of heat dissipation terminals are formed on the substrate; and a driver chip bonded to the substrate, wherein the driver chip includes a plurality of signal pins, a plurality of heat dissipation pins, and a driver chip body.

The signal pins are connected to the signal terminals, and the heat dissipation pins are connected to the heat dissipation terminals.

An embodiment of the present disclosure provides a display device including a COF. By disposing the heat dissipation pins on the driver chip, heat generated from the driver chip may be dissipated by the heat dissipation pins. Therefore, a large heat dissipation area of the driver chip may be realized, which effectively reduces temperature of the COF and solves the problem that temperatures of conventional COFs are too high.

In one embodiment, the COF further includes a heat dissipation component covering the driver chip.

In one embodiment, the heat dissipation pins are disposed on a middle portion of the driver chip.

In one embodiment, the heat dissipation pins are disposed on a periphery of the driver chip.

In one embodiment, the heat dissipation pins are disposed on one side of the driver chip.

In one embodiment, the heat dissipation pins are disposed on two sides of the driver chip.

In one embodiment, the heat dissipation terminals and the signal terminals are disposed on a same row.

In one embodiment, the heat dissipation terminals and the signal terminals are disposed on different rows.

In one embodiment, the heat dissipation terminals are disposed outwardly with respect to the signal terminals.

In one embodiment, shapes of the heat dissipation terminals are one or more of a circle, a rectangle, and an octagon.

In one embodiment, the COF further includes a heat dissipation component covering the driver chip.

According to the above embodiments: An embodiment of the present disclosure provides a COF and a display device. The COF includes a substrate and a driver chip. A plurality of signal terminals and a plurality of heat dissipation terminals are formed on the substrate. The driver chip is bonded to the substrate. The driver chip includes a plurality of signal pins and a plurality of heat dissipation pins. The signal pins are connected to the signal terminals, and the heat dissipation pins are connected to the heat dissipation terminals. By disposing the heat dissipation pins on the driver chip, heat generated from the driver chip may be dissipated by the heat dissipation pins. Therefore, a large heat dissipation area of the driver chip may be realized, which effectively reduces temperature of the COF and solves the problem that temperatures of conventional COFs are too high.

To sum up, the present disclosure has been described with a preferred embodiment thereof. The preferred embodiment is not intended to limit the present disclosure, and it is understood that many changes and modifications to the described embodiment can be carried out without departing from the scope and the spirit of the disclosure that is intended to be limited only by the appended claims.

What is claimed is:

1. A chip on film (COF), comprising:
a substrate, wherein a plurality of signal terminals and a plurality of heat dissipation terminals are formed on the substrate; and
a driver chip bonded to the substrate, wherein the driver chip comprises a plurality of signal pins and a plurality of heat dissipation pins;
wherein the signal pins are connected to the signal terminals, and the heat dissipation pins are connected to the heat dissipation terminals.

2. The COF of claim 1, wherein the heat dissipation pins are disposed on a middle portion of the driver chip.

3. The COF of claim 1, wherein the heat dissipation pins are disposed on a periphery of the driver chip.

4. The COF of claim 1, wherein the heat dissipation pins are disposed on a side of the driver chip.

5. The COF of claim 1, wherein the heat dissipation pins are disposed on two sides of the driver chip.

6. The COF of claim 1, wherein the heat dissipation terminals and the signal terminals are disposed on a same row.

7. The COF of claim 1, wherein the heat dissipation terminals and the signal terminals are disposed on different rows.

8. The COF of claim 1, wherein the heat dissipation terminals are disposed outwardly with respect to the signal terminals.

9. The COF of claim 1, wherein shapes of the heat dissipation terminals are one or more of a circle, a rectangle, and an octagon.

10. The COF of claim 1, wherein the COF further comprises a heat dissipation component covering the driver chip.

11. A display device, comprising a chip on film (COF);
wherein the COF comprises:
a substrate, wherein a plurality of signal terminals and a plurality of heat dissipation terminals are formed on the substrate; and
a driver chip bonded to the substrate, wherein the driver chip comprises a plurality of signal pins and a plurality of heat dissipation pins;
wherein the signal pins are connected to the signal terminals, and the heat dissipation pins are connected to the heat dissipation terminals.

12. The display device of claim 11, wherein the heat dissipation pins are disposed on a middle portion of the driver chip.

13. The display device of claim 11, wherein the heat dissipation pins are disposed on a periphery of the driver chip.

14. The display device of claim 11, wherein the heat dissipation pins are disposed on a side of the driver chip.

15. The display device of claim 11, wherein the heat dissipation pins are disposed on two sides of the driver chip.

16. The display device of claim 11, wherein the heat dissipation terminals and the signal terminals are disposed on a same row.

17. The display device of claim 11, wherein the heat dissipation terminals and the signal terminals are disposed on different rows.

18. The display device of claim 11, wherein the heat dissipation terminals are disposed outwardly with respect to the signal terminals.

19. The display device of claim 11, wherein shapes of the heat dissipation terminals are one or more of a circle, a rectangle, and an octagon.

20. The display device of claim 11, wherein the COF further comprises a heat dissipation component covering the driver chip.
